(19) United States
(12) Patent Application Publication
(10) Pub. No.: US 2025/0214343 A1
(43) Pub. Date: Jul. 3, 2025

(54) DROPLET DISCHARGE APPARATUS AND DROPLET DISCHARGE METHOD

(71) Applicant: SEMES CO., LTD., Cheonan-si (KR)

(72) Inventors: Yongdeuk CHEONG, Cheonan-si (KR); Hongjoo LEE, Cheonan-si (KR)

(73) Assignee: SEMES CO., LTD., Cheonan-si (KR)

(21) Appl. No.: 18/979,872

(22) Filed: Dec. 13, 2024

(30) Foreign Application Priority Data
Dec. 28, 2023 (KR) 10-2023-0193897

(51) Int. Cl. B41J 2/175; B41J 2/045

(52) U.S. Cl. CPC B41J 2/175; B41J 2/0454; B41J 2/04568

(57) ABSTRACT

In a droplet discharge method, a plurality of grids corresponding to areas of a substrate are set. A discharge amount for each grid is determined based on a difference in discharge amount according to a temperature change of ink to be discharged from nozzles that are designated for the plurality of grids respectively. An ink drop map for discharging ink having the discharge amount for each grid is created. Droplets are discharged through the nozzles according to the ink drop map to form a thick film having a predetermined thickness on the substrate.

### PRIORITY STATEMENT

This application claims priority under 35 U.S.C. § 119 to Korean Patent Application No. 10-2023-0193897, filed on Dec. 28, 2023 in the Korean Intellectual Property Office (KIPO), the contents of which are herein incorporated by reference in their entirety.

### BACKGROUND

### 1. Field

Embodiments of the present disclosure relate to a droplet discharge apparatus and a droplet discharge method, and more specifically, to a droplet discharge apparatus for discharge droplets using an inkjet printing manner and a droplet discharge method using the same.

### 2. Description of the Related Art

Before transporting a large panel for a large-area display device to equipment for a modularization process, a protective film may be formed on the large panel. Instead of a conventional protective film, a resin-based material may be printed using an inkjet printing method through a plurality of nozzles to form a thick film having a relatively large thickness on the entire surface of a large substrate. Since one or more heads have a limited width, the entire surface of the large substrate may be printed through a plurality of scans. In addition, since ink must be supplied to the head during printing in order to form a thick film having a large thickness through single printing, there is a problem that the temperature of the ink in the reservoir that supplies the ink to the nozzles decreases over time, and accordingly, the viscosity of the supplied ink increases, so that the amount of a droplet discharged through the nozzle decreases, and thus a thick film having a uniform thickness cannot be formed.

### SUMMARY

One object of the present disclosure is to provide a droplet discharge method capable of forming a thick film of uniform thickness.

Another object of the present disclosure is to provide a droplet discharge apparatus for performing the droplet discharge method.

According to example embodiments, a droplet discharge method includes determining a scan order of nozzles of an inkjet head to correspond to a substrate; supplying ink from a reservoir to the nozzles of the inkjet head; and discharging droplets through the nozzles corresponding to a first area and a second area of the substrate according to the scan order to form a thick film having a predetermined thickness on the substrate. In order to discharge the droplets, a first temperature of ink supplied to a first nozzle of the nozzles when discharging a first droplet on the first area of the substrate and a second temperature of ink supplied to a second nozzle of the nozzles when discharging a second droplet on the second area of the substrate are compared with each other, and when the second temperature is lower than the first temperature, a first control signal is outputted to the first nozzle for discharging the first droplet with a first discharge amount and a second control signal is outputted to the second nozzle for discharging the second droplet with a second discharge amount greater than the first discharge amount.

In example embodiments, determining the scan order of the nozzles may include determining a plurality of grids corresponding to the entire area of the substrate, and specifying the scan order of the nozzles for each of the plurality of grids.

In example embodiments, comparing the first temperature and the second temperature may include predicting a temperature change from the first temperature to the second temperature for the entire grids to calculate a time-series temperature gradient of ink for each grid; calculating a discharge amount for each grid based on a change in ink viscosity according to the time-series temperature gradient; and creating an ink drop map for discharging ink having the discharge amount for each grid.

In example embodiments, the ink drop map may have control signal data outputted to the nozzles designated for the grids respectively.

In example embodiments, outputting the first and second control signals may include outputting the first and second control signals corresponding to the control signal data to the first and second nozzles respectively.

In example embodiments, when the control signal data of the ink drop map represents 2-bit data, four different control signals corresponding to the control signal data may be generated.

In example embodiments, comparing the first temperature and the second temperature may include detecting temperature of ink in the reservoir.

In example embodiments, the discharge amount of the droplet discharged on the substrate through the first nozzle according to the first control signal may be the same as the discharge amount of the droplet discharged on the substrate through the second nozzle according to the second control signal.

In example embodiments, the thickness of the thick film may be within a range of 100 μm to 150 μm.

According to example embodiments, a droplet discharge method includes setting a plurality of grids corresponding to areas of a substrate; determining a discharge amount for each grid based on a difference in discharge amount according to a temperature change of ink to be discharged from nozzles that are designated for the plurality of grids respectively; creating an ink drop map for discharging ink having the discharge amount for each grid; and discharging droplets through the nozzles according to the ink drop map to form a thick film having a predetermined thickness on the substrate.

In example embodiments, setting the plurality of grids may include dividing the substrate into a plurality of scan lines; and setting a plurality of sub-grid maps corresponding to the plurality of scan lines respectively.

In example embodiments, determining the discharge amount for each grid may include detecting temperature of ink in a reservoir that supplies the ink to the nozzles.

In example embodiments, determining the discharge amount for each grid may include when discharging a first droplet at a first time point in a first area of the substrate according to the scan order of the nozzles and discharging a second droplet at a second time point in a second area of the substrate after a first time lapses, comparing a first temperature of ink received in the nozzle when discharging the first droplet in the first area with a second temperature of ink received in the nozzle when discharging the second droplet in the second area; predicting a temperature change from the first temperature to the second temperature for the plurality of grids to calculate a time-series temperature gradient of ink for each grid; and calculating the discharge amount for each grid based on a change in ink viscosity according to the time-series temperature gradient.

In example embodiments, the ink drop map may have control signal data outputted to the nozzles designated for the grids respectively.

In example embodiments, discharging the droplets through the nozzles according to the ink drop map may include outputting at least two different control signals corresponding to the control signal data to the nozzles corresponding to the grids.

In example embodiments, the discharge amounts of the droplets respectively discharged on the substrate through the nozzles according to the ink drop map are identical to each other.

In example embodiments, the thickness of the thick film may be within a range of 100 μm to 150 μm.

According to example embodiments, a droplet discharge method includes setting a plurality of grids corresponding to areas of a substrate; determining a scan order of nozzles for the plurality of grids; obtaining a first temperature of ink received in the nozzles when discharging a first droplet at a first time point in a first area of the substrate according to the scan order of the nozzles, and a second temperature of ink received in the nozzles when discharging a second droplet at a second time point in a second area of the substrate after a first time point has elapsed; predicting a temperature change from the first temperature to the second temperature for the entire grids to calculate a time-series temperature gradient of ink for each grid; calculating a discharge amount for each grid based on a change in ink viscosity according to the time-series temperature gradient; creating an ink drop map for discharging ink having the discharge amount for each grid; and discharging droplets through the nozzles according to the ink drop map to form a thick film having a predetermined thickness on the substrate.

In example embodiments, obtaining the first temperature and the second temperature may include detecting temperature of ink in a reservoir that supplies the ink to the nozzles.

In example embodiments, the discharge amounts of the droplets respectively discharged on the substrate through the nozzles according to the ink drop map may be identical to each other.

According to example embodiments, when creating an ink drop map for discharging droplets to a first area of a substrate through nozzles of a head assembly and discharging droplets to a second area of the substrate after a first time has elapsed, a first temperature of ink received in a first nozzle when discharging to the first area and a second temperature of ink received in a second nozzle when discharging to the second area may be compared. When the second temperature is determined to be lower than the first temperature, a waveform of a control signal may be adjusted so that an amount of ink discharged in the second area is greater than an amount of ink discharged in the first area in consideration of an increase in ink viscosity due to a decrease in temperature.

Accordingly, even if temperature of ink in the reservoir for supplying the ink to the nozzles cannot be increased to a desired temperature, the waveform of the control signal may be adjusted to discharge droplets having relatively large discharge amounts. Accordingly, even if the temperature of the ink supplied to the first and second nozzles gradually decreases as the printing time elapses, the discharge amounts of the droplets sequentially discharged from the first and second nozzles onto the substrate may be maintained constant, to thereby form a thick film having a uniform thickness over the entire area of the substrate.

However, effects of the present disclosure are not limited to the above-described effects, and may be variously expanded without departing from the idea and scope of the present disclosure.

### BRIEF DESCRIPTION OF THE DRAWINGS

FIG. 1 is a perspective view illustrating a droplet discharge apparatus in accordance with example embodiments.

FIG. 2 is a plan view illustrating the droplet discharge apparatus of FIG. 1.

FIG. 3 is a front view illustrating the droplet discharge apparatus of FIG. 1.

FIG. 4 is a side view illustrating the droplet discharge apparatus of FIG. 1.

FIG. 5 is a cross-sectional view illustrating an inkjet head and a reservoir of an inkjet head unit of FIG. 1.

FIG. 6 is a plan view illustrating a nozzle surface of the inkjet head unit of FIG. 5.

FIG. 7 is a cross-sectional view illustrating nozzles of the inkjet head of FIG. 5.

FIG. 8 is a block diagram illustrating a control portion of the droplet discharge apparatus of FIG. 1.

FIG. 9 is a plan view illustrating a grid map corresponding to the entire area of the substrate and nozzles corresponding to the grids of the grid map.

FIG. 10 is a view illustrating an ink drop map for discharging ink having a discharge amount for each grid.

FIGS. 11A, 11B, and 11C are graphs illustrating voltage waveforms of control signals outputted from the control portion according to the ink drop map of FIG. 10, respectively.

FIG. 12 is a view illustrating droplet patterns discharged from nozzles according to the ink drop map of FIG. 10.

FIG. 13A is a view illustrating swath patterns discharged from nozzles according to an ink drop map according to example embodiments.

FIG. 13B is a view illustrating thick film patterns formed by the swath patterns of FIG. 13A.

FIG. 14 is a view illustrating a swath pattern discharged from nozzles according to an ink drop map according to example embodiments.

FIG. 15 is a flowchart illustrating a droplet discharge method in accordance with example embodiments.

### DETAILED DESCRIPTION OF EXAMPLE EMBODIMENTS

Hereinafter, example embodiments will be explained in detail with reference to the accompanying drawings.

Since various modifications can be made to the present disclosure, and the present disclosure may have various forms, embodiments will be described in detail through the detailed description. This, however, is by no means to restrict the present disclosure to a specific disclosed form, and the present disclosure shall be construed as encompassing all modifications, equivalents, and substitutes included in the idea and technical scope of the present disclosure.

Terms used herein are intended to describe certain embodiments only, and shall by no means restrict the present disclosure. Unless the context explicitly indicates otherwise, expressions in a singular form include a meaning of a plural form. In the present disclosure, a term such as “comprising” or “including” is intended to designate the presence of characteristics, numbers, steps, operations, elements, parts, or combinations thereof described in the present disclosure, and shall not be construed to preclude any possibility of presence or addition of one or more other characteristics, numbers, steps, operations, elements, parts, or combinations thereof.

While describing each drawing, similar reference numerals will be used for similar elements. Terms such as “first” and “second” may be used to describe various elements, but the elements are not limited by the terms, and the terms may be used only to distinguish one element from another element.

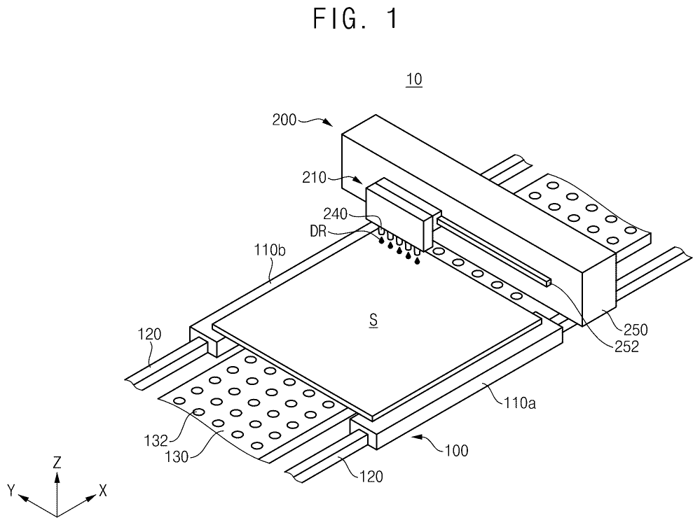

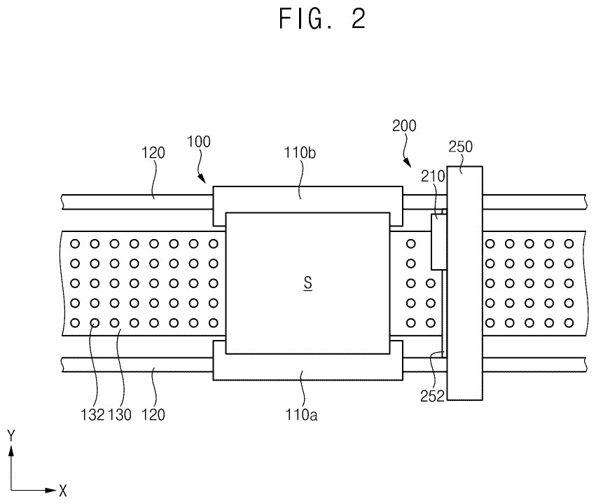

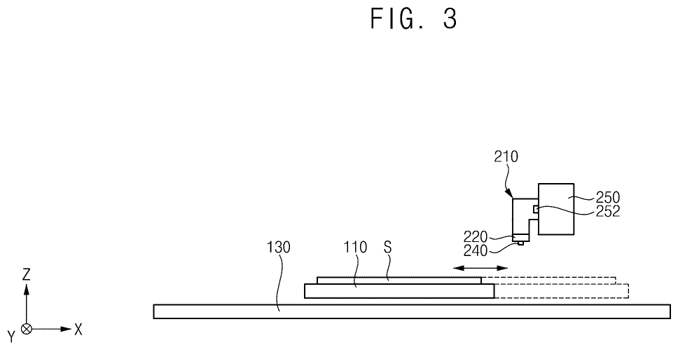

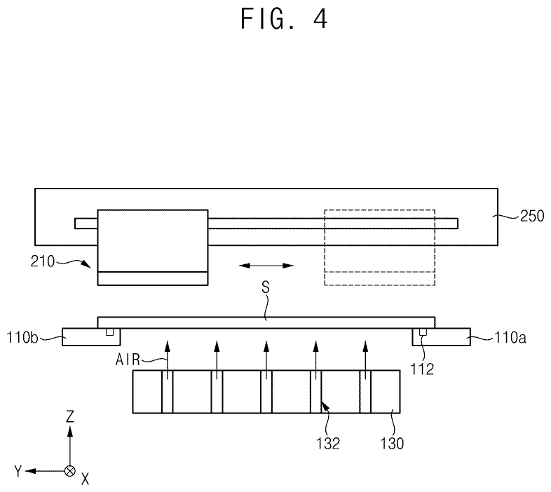

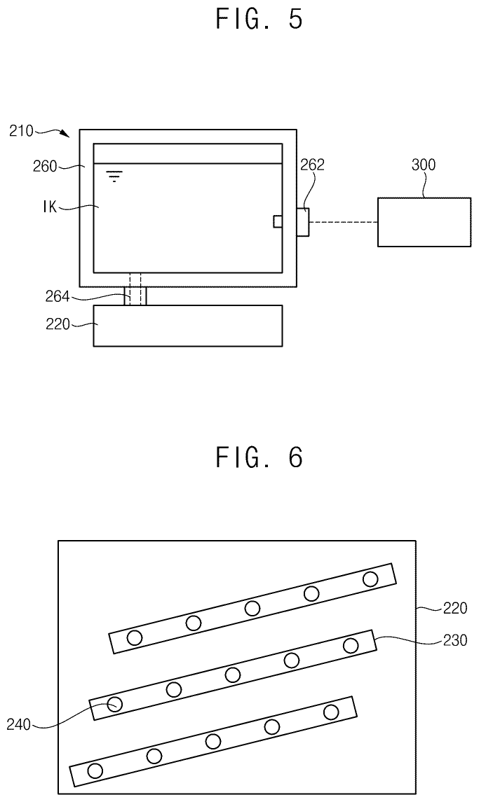

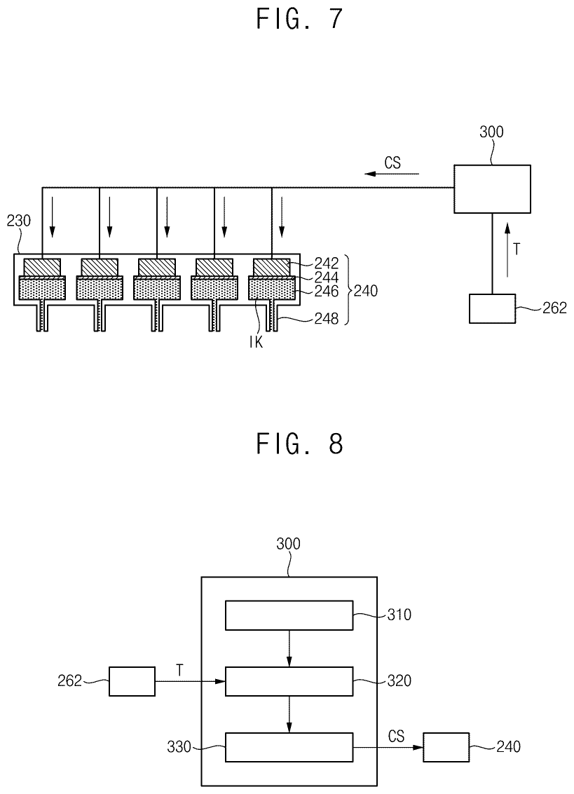

FIG. 1 is a perspective view illustrating a droplet discharge apparatus in accordance with example embodiments. FIG. 2 is a plan view illustrating the droplet discharge apparatus of FIG. 1. FIG. 3 is a front view illustrating the droplet discharge apparatus of FIG. 1. FIG. 4 is a side view illustrating the droplet discharge apparatus of FIG. 1. FIG. 5 is a cross-sectional view illustrating an inkjet head and a reservoir of an inkjet head unit of FIG. 1. FIG. 6 is a plan view illustrating a nozzle surface of the inkjet head unit of FIG. 5. FIG. 7 is a cross-sectional view illustrating nozzles of the inkjet head of FIG. 5.

Referring to FIGS. 1 to 7, a droplet discharge apparatus 10 may include a substrate support 100, a droplet discharge portion 200 configured to discharge droplets onto a substrate S supported by the substrate support 100, and a control portion 300 configured to control operations of the substrate support 100 and the droplet discharge portion 200.

In example embodiments, the droplet discharge apparatus 10 may be used to manufacture a large-area flat panel display (FPD), etc. The droplet discharge apparatus 10 may coat a chemical liquid on the substrate S using an inkjet printing method. For example, the substrate may include a display panel such as a liquid crystal display (LCD), an organic light emitting diode (OLED) displayer, etc. The droplet discharge apparatus 10 may print a resin-based material using an inkjet printing method through a plurality of nozzles to form a thick film having a large thickness on the entire surface of a large substrate, such as a protective film for protecting an OLED organic/inorganic film. A thickness of the thick film may be within a range of 100 μm to 150 μm. The chemical liquid may include an acrylic UV-curable resin.

As illustrated in FIGS. 1 to 4, the substrate support 100 may include a transfer portion 110 on which the substrate S is placed and a levitation portion 130 that levitates the substrate S.

The transfer portion 110 may include a pair of grippers 110a, 110b for adsorbing and supporting the substrate S. Each of the pair of grippers 110a, 110b may extend in one direction to correspond to one side of the substrate S. The pair of grippers 110a, 110b may be installed to be movable along guide rails 120 by a transfer mechanism. For example, the transfer mechanism may include a motor, a gear, a pulley, a belt, a ball screw, a linear motor, etc. Each of the guide rails 120 may extend in a first direction (X direction) and the guide rails 120 may be spaced apart from each other in a second direction (Y direction) perpendicular to the first direction.

The pair of grippers 110a, 110b may hold the substrate S by a vacuum adsorption method. An upper surface of the pair of grippers 110a, 110b may include an adsorption portion in which adsorption holes 112 are formed. Vacuum pressure may applied to the adsorption holes 112 so that both sides of the substrate S are adsorbed on the upper surface of the pair of grippers. Accordingly, the pair of grippers 110a, 110b may secure the substrate S and reciprocally move the substrate S in the first direction (X direction).

The levitation portion 130 may eject air to a lower portion of the substrate S to levitate the substrate S. The levitation portion 130 may be provided with a plurality of ejection holes 132 for ejecting air. The substrate S may be supported by an air floating method in which the substrate is floated by air pressure ejected from the plurality of injection holes 132.

The levitation portion 130 may extend along the first direction (X direction) from the transport conveyor through which the substrate S is loaded and unloaded to pass by the droplet discharge portion 200. When the substrate S is loaded onto the transport conveyor by a robot transport device, lifting pins may rise to raise the substrate S, the pair of grippers 110a, 110b may move below the substrate S, and then the lifting pins descend to transfer and settle the substrate S onto the adsorption portions of the pair of grippers 110a, 110b. The pair of grippers 110a, 110b on which the substrate S is mounted may move toward the droplet discharge portion 200 in the first direction (X direction) along the guide rails 120, and the droplet discharge portion 200 may discharge a liquid onto the substrate S that is adsorbed and supported by the pair of grippers 110a, 110b.

In example embodiments, the droplet discharge apparatus 10 may further include a droplet curing portion configured to cure the droplets discharged onto the substrate S. The substrate S on which the droplets are discharged may moves to the droplet curing portion, and the droplet curing portion may harden the droplets discharged onto the substrate S. For example, the droplet curing portion may include a light irradiation unit configured to irradiate the droplets with light. The light irradiation unit may include a heating lamp, an ultraviolet curing device, or the like.

In example embodiments, the droplet discharge portion 200 may include a head assembly 210 for ejecting droplets in an inkjet manner, and a gantry 250 supporting the head assembly 210. The head assembly 210 may be mounted and supported on the gantry 250 located above the substrate S.

The gantry 250 may have a support frame that extends in the second direction (Y direction) from above the pair of grippers 110a, 110b. The gantry 250 may be supported on frame support bars that extend in a third direction (Z direction) perpendicular to the first and second directions respectively, and the frame support bars may be installed to be movable along guides extending in the first direction (X direction) by a transport mechanism. Accordingly, the gantry 250 may be reciprocally moved in the first direction (X direction). The head assembly 210 may be mounted on a front side of the support frame of the gantry 250 by a bracket. A guide 252 may be installed on the front side of the support frame and may extend in the second direction (Y direction), and the bracket of the head assembly 210 may be installed to be movable along the guide 252 by a transport mechanism. Accordingly, the head assembly 210 may reciprocally move in the second direction (Y direction).

In example embodiments, the head assembly 210 may include a head pack assembly 220 having at least one inkjet head 230 mounted thereon. The head assembly 210 may include a reservoir 260 that is configured to accommodate and supply ink (IK) to the at least one inkjet head 230.

As illustrated in FIGS. 5 and 6, the head pack assembly 220 may include three inkjet heads 230. One reservoir 260 may supply the ink (IK) to the three inkjet heads 230. Alternatively, three reservoirs 260 may be provided to supply ink (IK) to the three inkjet heads 260 respectively. Each of the inkjet heads 230 may extend in one direction, and each of the inkjet heads 230 may include a plurality of nozzles 240 that are spaced apart at a predetermined interval. Each of the inkjet heads 230 may be arranged to be inclined so as to have a predetermined angle with respect to the first direction (X direction). Alternatively, each of the inkjet heads 230 may be arranged such that extension directions of the inkjet heads are parallel to the first direction (X direction). The inkjet heads 230 may be arranged to be spaced apart from each other along the second direction (Y direction). The inkjet heads 230 may be offset aligned from each other in the first direction (X direction). When viewed in the second direction (Y direction), the inkjet heads 230 may be arranged to partially overlap each other. It will be understood that the number and arrangement of the inkjet heads 230, the number and arrangement of the nozzles 240, etc. are provided as examples and the present inventive concept is not limited thereto.

Since a width of one scan covered by the nozzles 240 of the head assembly 210 is smaller than a width of the substrate S, the head assembly 210 may print the entire surface of the substrate S through a plurality of scans. That is, when the head assembly 210 is at a first position, the substrate S may moves in the first direction (X direction) and the head assembly 210 may eject droplets (DR) to form a first dot pattern along a first scan line. Then, when the head assembly 210 moves in the second direction (Y direction) by a preset distance and is at a second position, the substrate S may moves in the first direction (X direction) and the head assembly 210 may eject droplets (DR) to form a second dot pattern along a second scan line. Then, the head assembly 210 may repeatedly eject droplets (DR) while sequentially moving by the preset distance in the second direction (Y direction) until a thick film is formed on the entire surface of the substrate S.

As illustrated in FIG. 7, the inkjet head 230 may eject ink (IK) in a piezoelectric manner. Each of the nozzles 240 may include a piezoelectric element 242, an ink chamber 246 adjacent to the piezoelectric element 242, an ejection port 248 opened to the outside from the ink chamber 246, and a vibration plate 244 disposed between the piezoelectric element 242 and the ink chamber 246. The piezoelectric element 242 may control a volume of the ink chamber 246. The piezoelectric element 242 may include a piezoelectric body. The piezoelectric body may include a material whose shape changes when an electric signal is applied. When an electrical signal as a control signal (CS) from the control portion 300 is applied to the piezoelectric element 242 of the nozzle 240, the shape of the piezoelectric element 242 may change to apply pressure to the ink chamber 246 through the vibration plate 244, and accordingly, the ink (IK) accommodated inside the ink chamber 246 may be ejected toward the substrate S through the ejection port 248, to perform an inkjet printing process.

The ink chamber 246 may accommodate ink (IK) therein. For example, the volume of ink (IN) accommodated in the ink chamber 246 may be within a range of 4 cc to 8 cc. As the printing processes are performed on the substrate S progresses, the ink (IN) in the ink chamber 246 may be consumed, and the ink chamber 246 may receive ink (IN) from the reservoir 260 through a flow path pipe 264 to maintain a certain amount of ink (IK).

The vibration plate 244 may be arranged between the piezoelectric element 242 and the ink chamber 244. The vibration plate 244 may be made of an elastic material, and when a control signal (CS) is applied to the piezoelectric element 242, the shape may be changed and bent according to the deformation of the piezoelectric element 242, thereby changing the volume of the ink chamber 246. For example, the control signal (CS) may be a voltage pulse signal having a preset waveform. When a voltage signal including pulses of a plus (+) waveform and a minus (−) waveform is applied, the vibration plate 244 may be deformed so that the nozzle 240 may discharge a droplet (DR) having a discharge amount corresponding to the waveform.

In example embodiments, the head assembly 210 may further include a temperature sensor 262 for measuring the temperature of ink (IK) within the reservoir 260. The temperature sensor 260 may be installed on one side wall of the reservoir 260 and may measure the temperature of ink (IK) contained within the reservoir 260. The temperature sensor 260 may be connected to the control portion 300, and the control portion 300 may receive ink temperature data (T) measured by the temperature sensor 262. The temperature sensor 262 may measure a temperature change of ink (IK), which is supplied to the nozzles 240, during the entire printing process for the substrate S. The control portion 300 may calculate the time-series temperature gradient, i.e., the time-series temperature change for the entire area, of the ink (IK) supplied to the nozzles 240 when ejecting the droplets (DR) along the scan line of the substrate S during the printing process, based on the temperature change data.

For example, in order to form a thick film with a large thickness on the entire surface of the substrate S, one nozzle 240 may eject 10 cc or more of ink (IK). Accordingly, since the amount of ink in the ink chamber 246 of the nozzle 240 is insufficient while printing on the substrate S is in progress, the reservoir 260 may supply ink (IN) to the ink chamber 246 of the nozzle 240. A heater may be installed in the reservoir 260 to maintain the temperature of the ink (IK) inside the reservoir 260 at a constant temperature. For example, the temperature of the ink (IK) inside the reservoir 260 may be maintained at 36° C. However, as printing progresses, the temperature of the ink (IK) inside the reservoir 260 may gradually decrease to 35° C. or less. As the temperature of the ink (IK) gradually decreases, the viscosity of the ink (IK) may increase, so that even if a voltage signal of the same waveform is applied to the piezoelectric element 242 of the nozzle 240, the discharge amount of the droplet discharged from the nozzle 240 may decrease. That is, although the vibration plate 244 is deformed to the same size by the preset voltage signal, the discharge amount of the droplet (DR) discharged through the ejection port 248 of the ink chamber 246 may decrease due to the increase in viscosity. Accordingly, as printing progresses, the thickness of the thick film formed on the substrate S may gradually decrease.

The control portion 300 may determine a discharge amount for each of grids corresponding to the entire area of the substrate S based on the discharge amount difference according to the time-series temperature change of the ink (IK) inside the reservoir 260, create an ink drop map according to the discharge amount for each grid, and adjust control signals (CS) for controlling the nozzles 240 according to the ink drop map.

Hereinafter, operations of the control portion for adjusting the control signals for controlling the discharge amount of the nozzles will be described.

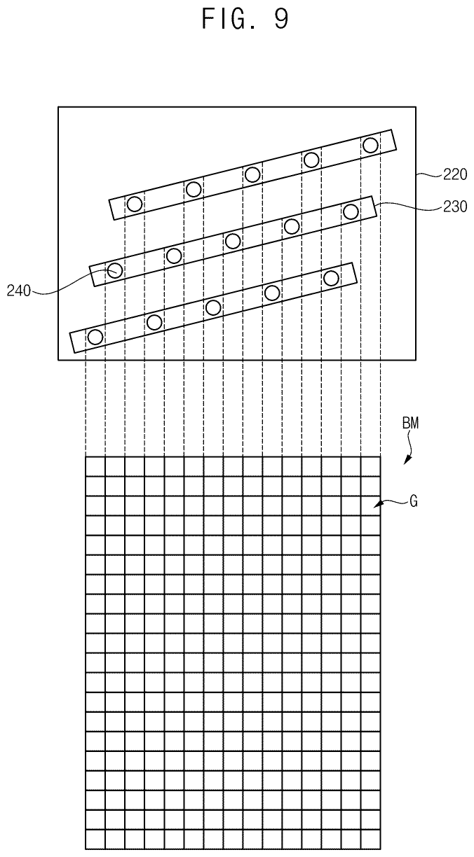

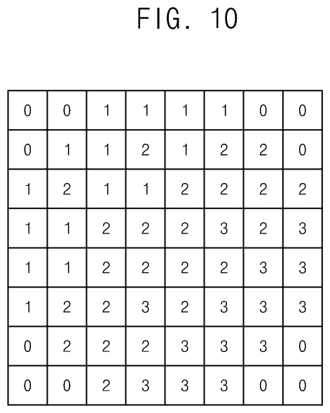

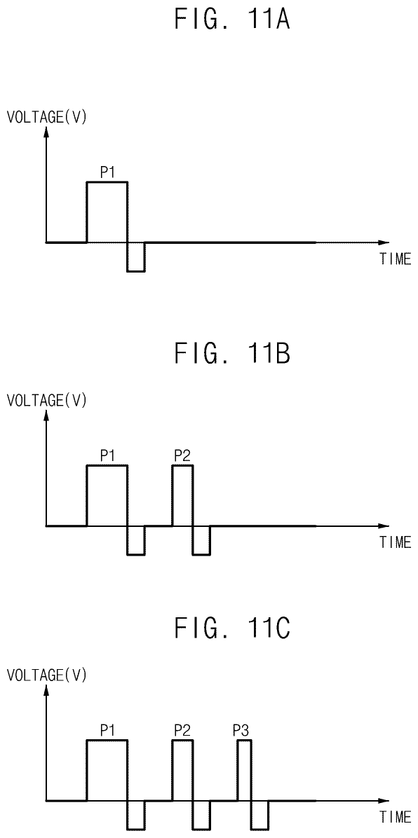

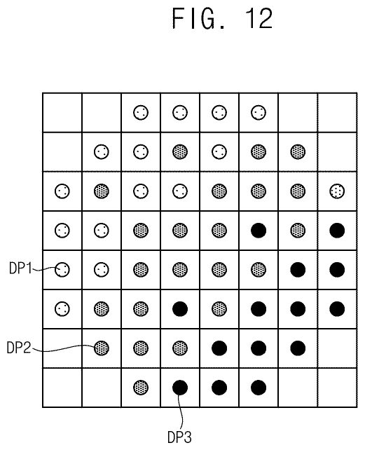

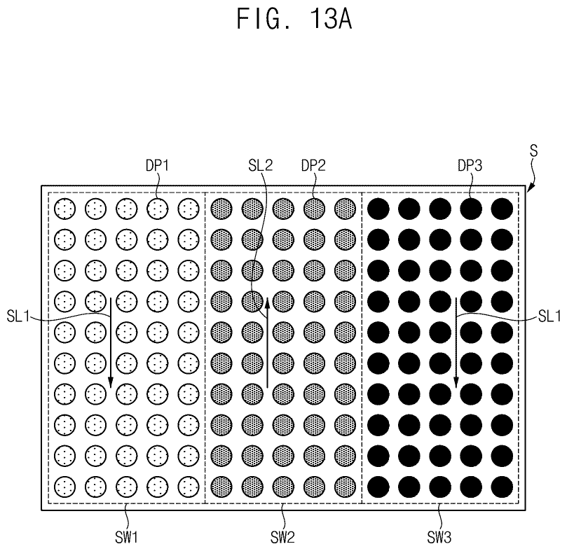

FIG. 8 is a block diagram illustrating a control portion of the droplet discharge apparatus of FIG. 1. FIG. 9 is a plan view illustrating a grid map corresponding to the entire area of the substrate and nozzles corresponding to the grids of the grid map. FIG. 10 is a view illustrating an ink drop map for discharging ink having a discharge amount for each grid. FIGS. 11A, 11B, and 11C are graphs illustrating voltage waveforms of control signals outputted from the control portion according to the ink drop map of FIG. 10, respectively. FIG. 12 is a view illustrating droplet patterns discharged from nozzles according to the ink drop map of FIG. 10.

Referring to FIGS. 8 to 12, the control portion 300 of the droplet discharge apparatus 10 may include a grid map determination portion 310, an ink drop map determination portion 320, and an ejection driver 330.

In particular, the grid map determination portion 310 may create a grid map BM having a plurality of grids G corresponding to the entire area of the substrate S. The substrate S may be divided into rectangular areas, i.e., grids G, having two sides parallel to a row direction and two sides parallel to a column direction. At this time, the position of each grid may be expressed by a unique coordinate according to the order in the row direction and the column direction.

As illustrated in FIG. 9, each of the nozzles 240 of the head assembly 210 may be assigned to each of the grids G arranged in one row in the grid map BM. When the head assembly 210 is at a predetermined position over the substrate S, the plurality of nozzles 240 may correspond to predetermined coordinates on the grid map BM. When the head assembly 210 moves along a scan line on the substrate S, the nozzles 240 may independently (e.g., sequentially or simultaneously) discharge droplets (DR) onto areas of the substrate S each corresponding to the grids G arranged in one row. The column direction may correspond to the scan direction, and when the head assembly 210 moves along a plurality of scan lines, the grid map BM may include a plurality of sub-grid maps corresponding to each of the plurality of scan lines.

The ink drop map determination portion 320 may determine a discharge amount for each grid based on the discharge amount difference according to the temperature change of the ink (IK) to be supplied to the nozzles 240 and create an ink drop map for discharging ink having the discharge amount for each grid. The ink drop map determination portion 320 may receive temperature data (T) of the ink (IK) inside the reservoir 260 from the temperature sensor 262 and calculate the time-series temperature gradient of the ink (IK) supplied to the nozzles 240 during the entire printing process for the substrate (S). The ink drop map determination portion 320 may calculate the ink discharge amount difference of the nozzles 240 according to the time-series temperature gradient of the ink (IK) inside the reservoir 260 and determine the discharge amount for each grid based on the calculated ink discharge amount difference, and create an ink drop map according to the discharge amount for each grid.

According to the scan order of the nozzles 240 according to the grid map BM, the head assembly 210 may discharge a first droplet at a first time point in a first area of the substrate S and discharge a second droplet at a second time point in a second area of the substrate S after a first time has elapsed. The ink drop map determination portion 320 may compare a first temperature of ink (IK) received in the nozzle 240 when ejecting the first droplet in the first area and a second temperature of ink (IK) received in the nozzle 240 when ejecting the second droplet in the second area. The ink drop map determination portion 320 may perform a temperature change from the first temperature to the second temperature for the entire grid map BM to calculate a time-series temperature gradient of ink (IK) for each grid. The ink drop map determination portion 320 may determine the discharge amount for each grid so that the ink discharge amount in the second area is greater than the ink discharge amount in the first area by considering the increase in ink viscosity due to a decrease in temperature when the second temperature is determined to be lower than the first temperature, and may create the ink drop map according to the discharge amount for each grid.

As illustrated in FIG. 10, the ink drop map may indicate an discharge timing and ink discharge amount of the nozzle 240 designated for each of the grids. The ink drop map may be a bitmap in gray level indicating a control signal output to the nozzle 240 corresponding to each grid. In the ink drop map, each grid may indicate data for the control signal output to the corresponding nozzle 240. For example, when the data for the control signal has 2 bits of data, “1” may be output as a signal for outputting a first control signal, “2 (binary 10” may be output as a signal for outputting a second control signal, and “3 (binary 11)” may be output as a signal for outputting a third control signal. That is, when the output data has 2 bits of data, 4 control signals may be generated. When the data for the control signal has 3 bits of data, 8 control signals may be generated.

The ejection driver 330 may output a control signal (CS) according to the ink drop map to the piezoelectric element 242 of the nozzle 240 corresponding to each grid.

As illustrated in FIGS. 11A, 11B and 11C, the ejection driver 330 may output a first control signal, a second control signal, and a third control signal corresponding to 2-bit control signal data. As illustrated in FIG. 11A, the first control signal may be a unit pulse of one cycle that includes alternate pulses of a plus (+) waveform and a minus (−) waveform. As illustrated in FIG. 11B, the second control signal may include two different unit pulses. As illustrated in FIG. 11C, the third control signal may include three different unit pulses. It will be understood that the voltage waveforms of the first to third control signals are not limited thereto.

The nozzle 240 may form a dot pattern by ejecting a droplet (DR) on a corresponding area of the substrate S corresponding to each grid D in response to a control signal (CS) from the ejection driver 330.

As illustrated in FIG. 12, the nozzle 240 may eject a droplet (DR) having a first discharge amount in response to the first control signal to form a first dot pattern DP1 on the substrate S, eject a droplet (DR) having a second discharge amount in response to the second control signal to form a second dot pattern DP2 on the substrate S, and eject a droplet (DR) having a third discharge amount in response to the third control signal to form a third dot pattern DP3 on the substrate S.

When the temperature of the ink (IK) in the reservoir 260 is maintained the same as the printing time of the substrate S elapses, the second discharge amount may be greater than the first discharge amount and the third discharge amount may be greater than the second discharge amount. In this case, a thickness of the second droplet pattern DP2 may be smaller than a thickness of the first droplet pattern DP1 and a thickness of the third droplet pattern DP3 may be smaller than the thickness of the second droplet pattern DP2.

On the other hand, when the temperature of the ink (IK) in the reservoir 260 gradually drops as the printing time of the substrate S elapses, the viscosity of the ink (IK) may gradually increase, so that the first discharge amount actually discharged from the nozzle 240 in response to the first control signal may be equal to the second discharge amount actually discharged from the nozzle 240 in response to the second control signal, and the third discharge amount actually discharged from the nozzle 240 in response to the third control signal may be equal to the second discharge amount. In this case, the thickness of the second droplet pattern DP2 may be equal to the thickness of the first droplet pattern DP1, and the thickness of the third droplet pattern DP3 may be equal to the thickness of the second droplet pattern DP2.

As described above, when creating the ink drop map for discharging droplets (DR) to the first area of the substrate S through the nozzles 240 of the head assembly 210 and discharging droplets (DR) to the second area of the substrate S after the first time has elapsed, the first temperature of ink (IK) received in the nozzles 240 when discharging to the first area and the second temperature of ink (IK) received in the nozzles 240 when discharging to the second area may be compared. When the second temperature is determined to be lower than the first temperature, the waveforms of the control signal may be adjusted so that the amount of ink discharged in the second area is greater than the amount of ink discharged in the first area in consideration of the increase in ink viscosity due to a decrease in temperature.

Accordingly, even if the temperature of the ink in the reservoir 260 for supplying the ink (IK) to the nozzles 240 cannot be increased to a desired temperature, the waveform of the control signal may be adjusted to discharge droplets having relatively large discharge amounts. Accordingly, even if the temperature of the ink (IK) supplied to the nozzles 240 gradually decreases as the printing time elapses, the discharge amounts of the droplets (DR) sequentially discharged from the nozzles 240 onto the substrate S may be maintained constant, to thereby form a thick film having a uniform thickness over the entire area of the substrate S.

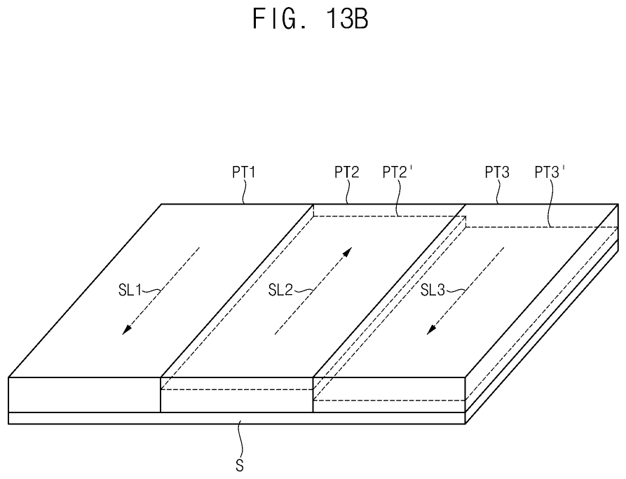

FIG. 13A is a view illustrating swath patterns discharged from nozzles according to an ink drop map according to example embodiments. FIG. 13B is a view illustrating thick film patterns formed by the swath patterns of FIG. 13A.

Referring to FIGS. 13A and 13B, in case that a head assembly 210 sequentially moves along first, second, and third scan lines SL1, SL2, SL3, a first swath pattern SW1 may be discharged to a first area of the substrate S along the first scan line SL1 through the nozzles 240 of the head assembly 210, and after a first time elapses, a second swath pattern SW2 may be discharged to a second area of the substrate S along the second scan line SL2, and after a second time elapses, a third swath pattern SW3 may be discharged to a third area of the substrate S along the third scan line SL3.

In this case, a grid map may include first, second and third sub-grid maps corresponding to the first, second and third scan lines SL1, SL2, SL3 respectively, and the ink drop map may include first, second and third sub-ink drop maps corresponding to the first, second and third sub-grid maps respectively. The nozzles 240 of the head assembly 210 may discharge the first swath pattern SW1 according to the first sub-ink drop map, the second swath pattern SW2 according to the second sub-ink drop map, and the third swath pattern (SW3) according to the third sub-ink drop map.

The first temperature of the ink (IK) accommodated in the nozzles 240 when discharging in the first area, the second temperature of the ink (IK) accommodated in the nozzles 240 when discharging in the second region, and the third temperature of the ink (IK) accommodated in the nozzles 240 when discharging in the third region may be compared with each other.

When it is determined that the second temperature is lower than the first temperature and the third temperature is lower than the second temperature, the grids in the first sub-ink drop map may have first control signal data for discharging a first ink discharge amount, the grids in the second sub-ink drop map may have second control signal data for discharging the second ink discharge amount greater than the first ink discharge amount, and the grids in the third sub-ink drop map may have third control signal data for discharging the third ink discharge amount greater than the second ink discharge amount.

Due to the increase in ink viscosity due to the decrease in temperature, a thickness of each of second dot patterns DP2 of the second swath pattern SW2 discharged according to the second sub ink drop map may be the same as a thickness of each of first dot patterns DP1 of the first swath pattern SW1 discharged according to the first sub ink drop map, and a thickness of each of third dot patterns DP3 of the third swath pattern SW3 discharged according to the third sub ink drop map may be the same as the thickness of each of the second dot patterns DP2 of the second swath pattern SW2 discharged according to the second sub ink drop map.

Accordingly, a thickness of a first thick film pattern PT1 formed by the first swath pattern SW1, a thickness of a second thick film pattern PT2 formed by the second swath pattern SW2, and a thickness of a third thick film pattern PT3 formed by the third swath pattern SW3 may be the same as each other.

On the other hand, even if it is determined that the second temperature is lower than the first temperature and the third temperature is lower than the second temperature, when all of the grids in the first sub ink drop map, the grids in the second sub ink drop map, and the grids in the third sub ink drop map have the same first control signal data, due to an increase in ink viscosity according to a decrease in temperature, the thickness of the second thick film pattern PT2′ formed by the second swath pattern SW2 may be smaller than the thickness of the first thick film pattern PT1′ formed by the first swath pattern SW1, and the thickness of the third thick film pattern PT3′ formed by the third swath pattern SW3 may be smaller than the thickness of the second thick film pattern PT2′ formed by the second swath pattern SW2.

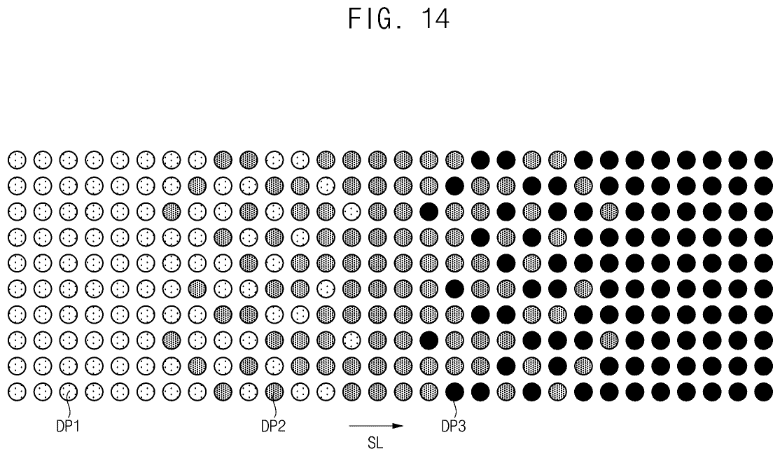

FIG. 14 is a view illustrating a swath pattern discharged from nozzles according to an ink drop map according to example embodiments.

Referring to FIG. 14, when a head assembly 210 moves along one scan line (SL), a swath pattern may be ejected through nozzles 240 of the head assembly 210 according to an ink drop map. Droplets (DR) may be discharged to a first area of a substrate S through the nozzles 240 of the head assembly 210, and after a first time elapses, droplets (DR) may be discharged to a second area of the substrate S, and after a second time elapses, droplets (DR) may be ejected to a third area of the substrate S.

In this case, the grid map can include a first group of grids corresponding to the first area, a second group of grids corresponding to the second area, and a third group of grids corresponding to the third area.

When it is determined that a second temperature of the ink (IK) accommodated in the nozzles 240 when discharging in the second area is lower than a first temperature of the ink (IK) accommodated in the nozzles 240 when discharging in the first area, and a third temperature of the ink (IK) accommodated in the nozzles 240 when discharging in the third area is lower than the second temperature, the grids of the first group in the ink drop map may have first control signal data for discharging the first ink discharge amount, the grids of the second group may have second control signal data for discharging the second ink discharge amount greater than the first ink discharge amount, and the grids of the third group may have third control signal data for discharging the third ink discharge amount greater than the second ink discharge amount.

Due to the increase in ink viscosity due to the decrease in temperature, the dot patterns of the swath pattern SW ejected according to the ink drop map may have the same thicknesses. Accordingly, a thick film pattern formed by the swath pattern SW may have a uniform thickness.

Hereinafter, a method of discharging droplets onto a substrate using the droplet discharge apparatus of FIG. 1 will be described.

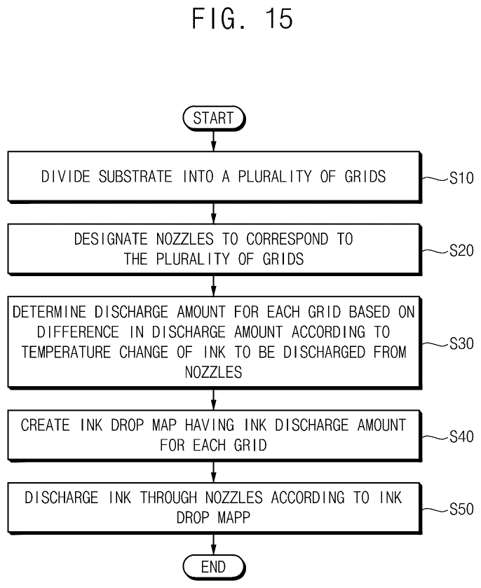

FIG. 15 is a flowchart illustrating a droplet discharge method in accordance with example embodiments.

Referring to FIGS. 1 to 15, first, a substrate S may be divided into a plurality of grids (S10), and nozzles 240 of a head assembly 210 may be designated to correspond to the plurality of grids respectively (S20).

In example embodiments, in order to perform an inkjet printing process, the substrate S may be placed on a pair of grippers 110a, 110b, and the substrate S may be moved to an initial position below a gantry 250 of a droplet discharge portion 200. Then, the head assembly 210 may be moved to the initial position along a guide 252 of the gantry 250.

Since a scan width covered by the nozzles 240 of the head assembly 210 is smaller than a width of the substrate S, the head assembly 210 may be controlled to move along a plurality of scan lines in order to print the entire surface of the substrate S.

As illustrated in FIGS. 8 and 9, a grid map determination portion 310 of a control portion 300 may create a grid map BM having the plurality of grids G corresponding to the areas, i.e., the entire area of the substrate S. Each of the nozzles 240 of the head assembly 210 may be assigned to each of the grids G arranged in one row in the grid map BM. When the head assembly 210 is at a predetermined position above the substrate S, the plurality of nozzles 240 may correspond to predetermined coordinates on the grid map BM. As the head assembly 210 moves along a scan line on the substrate S, the nozzles 240 may independently (sequentially or simultaneously) eject droplets (DR) onto areas of the substrate S each corresponding to the grids G arranged in one row.

Then, a discharge amount for each grid may be determined based on a difference in discharge amount according to a temperature change of ink (IK) to be discharged from the nozzles 240 (S30), and an ink drop map for discharging the ink (IK) having the discharge amount for each grid may be created (S40).

In example embodiments, an ink drop map determination portion 320 of the control portion 300 may receive temperature data T of the ink (IK) inside the reservoir 260 from a temperature sensor 262, and may calculate time-series temperature gradient of the ink (IK) supplied to the nozzles 240 during the entire printing process for the substrate S. The ink drop map determination portion 320 may calculate the difference in ink discharge amount of the nozzles 240 according to the time-series temperature gradient of the ink (IK) inside the reservoir 260, determine the discharge amount for each grid based on the calculated difference in ink discharge amount, and may create the ink drop map according to the discharge amount for each grid.

According to the scan order of the nozzles 240 according to the grid map BM, the head assembly 210 may discharge droplet (DR) to a first area of the substrate S and discharge droplet (DR) to a second area of the substrate S after a first time has elapsed. The ink drop map determination portion 320 may compare a first temperature of the ink (IK) received in the first nozzle when discharging the droplets (DR) to the first area and a second temperature of the ink (IK) received in the second nozzle when discharging the droplets (DR) to the second area. The second nozzle may be the same as or different from the first nozzle. The ink drop map determination portion 320 may predict a temperature change from the first temperature to the second temperature for the entire grid map BM to calculate the time-series temperature gradient of ink (IK) for each grid. When the ink drop map determination portion 320 determines that the second temperature is lower than the first temperature, the ink drop map determination portion 320 may determine the discharge amount for each grid so that the ink discharge amount in the second area is greater than the ink discharge amount in the first area by considering an increase in ink viscosity due to the decrease in temperature, and may create the ink drop map according to the discharge amount for each grid.

The ink drop map may represent the ink discharge amount of the nozzle 240 designated for each of the grids. The ink drop map may be a bitmap in gray level representing a control signal output to the nozzle 240 corresponding to each grid. In the ink drop map, each grid may represent data for a control signal output to the corresponding nozzle 240. For example, if the data for the control signal has 2 bits of data, “1” may be output as a signal for outputting a first control signal, “2 (binary 10” may be output as a signal for outputting a second control signal, and “3 (binary 11)” may be output as a signal for outputting a third control signal. That is, if the output data represents 2 bits of data, four control signals may be generated.

Then, ink (IK) may be discharged through the nozzles 240 of the head assembly 210 according to the ink drop map (S50).

In example embodiments, an ejection driver 330 of the control portion 300 may output a control signal (CS) according to the ink drop map to a piezoelectric element 242 of the nozzle 240 corresponding to each grid.

For example, the nozzle 240 may discharge a droplet (DR) having a first discharge amount in response to the first control signal to form a first dot pattern DP1 on the substrate S, discharge a droplet (DR) having a second discharge amount in response to the second control signal to form a second dot pattern DP2 on the substrate S, and discharge a droplet (DR) having a third discharge amount in response to the third control signal to form a third dot pattern DP3 on the substrate S. As the printing process time of the substrate S elapses and the temperature of the ink (IK) in the reservoir 260 gradually decreases, the viscosity of the ink (IK) may gradually increases, so that the first discharge amount actually discharged from the nozzle 240 in response to the first control signal may be equal to the second discharge amount actually discharged from the nozzle 240 in response to the second control signal, and the third discharge amount actually discharged from the nozzle 240 in response to the third control signal may be equal to the second discharge amount. In this case, a thickness of the second droplet pattern DP2 may be equal to a thickness of the first droplet pattern DP1, and a thickness of the third droplet pattern DP3 may be equal to a thickness of the second droplet pattern DP2.

Accordingly, even if the temperature of the ink in the reservoir 260 for supplying the ink (IK) to the nozzles 240 during one printing over the entire area of the substrate S cannot be increased to a desired temperature, a waveform of the control signal may be adjusted to discharge droplets having a relatively large discharge amount. Accordingly, a thick film having a uniform thickness may be formed over the entire area of the substrate S.

Then, the substrate S on which the droplets are discharged may move to a droplet curing portion, and the droplet curing portion may harden the droplets ejected on the substrate S. For example, the droplet curing portion may include a light irradiation unit configured to irradiating the droplets with light.

Although example embodiments of the present disclosure have been described above, it will be understood by a person having ordinary skill in the art that various modifications and changes can be made to the present disclosure without departing from the idea and scope of the present disclosure as set forth in the appended claims.

What is claimed is:

1. A droplet discharge method, comprising:
determining a scan order of nozzles of an inkjet head to correspond to a substrate;
supplying ink from a reservoir to the nozzles of the inkjet head; and
discharging droplets through the nozzles corresponding to a first area and a second area of the substrate according to the scan order to form a thick film having a predetermined thickness on the substrate,
wherein discharging the droplets comprises:
comparing a first temperature of ink supplied to a first nozzle of the nozzles when discharging a first droplet on the first area of the substrate and a second temperature of ink supplied to a second nozzle of the nozzles when discharging a second droplet on the second area of the substrate; and
when the second temperature is lower than the first temperature, outputting a first control signal to the first nozzle for discharging the first droplet with a first discharge amount and outputting a second control signal to the second nozzle for discharging the second droplet with a second discharge amount greater than the first discharge amount.

2. The droplet discharge method of claim 1, wherein determining the scan order of the nozzles includes:
determining a plurality of grids corresponding to the entire area of the substrate; and
specifying the scan order of the nozzles for each of the plurality of grids.

3. The droplet discharge method of claim 2, wherein comparing the first temperature and the second temperature includes:
predicting a temperature change from the first temperature to the second temperature for the entire grids to calculate a time-series temperature gradient of ink for each grid;
calculating a discharge amount for each grid based on a change in ink viscosity according to the time-series temperature gradient; and
creating an ink drop map for discharging ink having the discharge amount for each grid.

4. The droplet discharge method of claim 3, wherein the ink drop map has control signal data outputted to the nozzles designated for the grids respectively.

5. The droplet discharge method of claim 4, wherein outputting the first and second control signals includes outputting the first and second control signals corresponding to the control signal data to the first and second nozzles respectively.

6. The droplet discharge method of claim 4, wherein, when the control signal data of the ink drop map represents 2-bit data, four different control signals corresponding to the control signal data are generated.

7. The droplet discharge method of claim 1, wherein comparing the first temperature and the second temperature includes detecting temperature of ink in the reservoir.

8. The droplet discharge method of claim 1, wherein the discharge amount of the droplet discharged on the substrate through the first nozzle according to the first control signal is the same as the discharge amount of the droplet discharged on the substrate through the second nozzle according to the second control signal.

9. The droplet discharge method of claim 1, wherein the thickness of the thick film is within a range of 100 μm to 150 μm.

10. A droplet discharge method, comprising:
setting a plurality of grids corresponding to areas of a substrate;
determining a discharge amount for each grid based on a difference in discharge amount according to a temperature change of ink to be discharged from nozzles that are designated for the plurality of grids respectively;
creating an ink drop map for discharging ink having the discharge amount for each grid; and
discharging droplets through the nozzles according to the ink drop map to form a thick film having a predetermined thickness on the substrate.

11. The droplet discharge method of claim 10, wherein setting the plurality of grids includes:
dividing the substrate into a plurality of scan lines; and
setting a plurality of sub-grid maps corresponding to the plurality of scan lines respectively.

12. The droplet discharge method of claim 10, wherein determining the discharge amount for each grid includes detecting temperature of ink in a reservoir that supplies the ink to the nozzles.

13. The droplet discharge method of claim 10, wherein determining the discharge amount for each grid includes:
when discharging a first droplet at a first time point in a first area of the substrate according to the scan order of the nozzles and discharging a second droplet at a second time point in a second area of the substrate after a first time lapses, comparing a first temperature of ink received in the nozzle when discharging the first droplet in the first area with a second temperature of ink received in the nozzle when discharging the second droplet in the second area;
predicting a temperature change from the first temperature to the second temperature for the plurality of grids to calculate a time-series temperature gradient of ink for each grid; and
calculating the discharge amount for each grid based on a change in ink viscosity according to the time-series temperature gradient.

14. The droplet discharge method of claim 10, wherein the ink drop map has control signal data outputted to the nozzles designated for the grids respectively.

15. The droplet discharge method of claim 14, wherein discharging the droplets through the nozzles according to the ink drop map includes outputting at least two different control signals corresponding to the control signal data to the nozzles corresponding to the grids.

16. The droplet discharge method of claim 10, wherein the discharge amounts of the droplets respectively discharged on the substrate through the nozzles according to the ink drop map are identical to each other.

17. The droplet discharge method of claim 10, wherein the thickness of the thick film is within a range of 100 μm to 150 μm.

18. A droplet discharge method, comprising:
setting a plurality of grids corresponding to areas of a substrate;
determining a scan order of nozzles for the plurality of grids;
obtaining a first temperature of ink received in the nozzles when discharging a first droplet at a first time point in a first area of the substrate according to the scan order of the nozzles, and a second temperature of ink received in the nozzles when discharging a second droplet at a second time point in a second area of the substrate after a first time point has elapsed;
predicting a temperature change from the first temperature to the second temperature for the entire grids to calculate a time-series temperature gradient of ink for each grid;
calculating a discharge amount for each grid based on a change in ink viscosity according to the time-series temperature gradient;
creating an ink drop map for discharging ink having the discharge amount for each grid; and
discharging droplets through the nozzles according to the ink drop map to form a thick film having a predetermined thickness on the substrate.

19. The droplet discharge method of claim 18, wherein obtaining the first temperature and the second temperature includes detecting temperature of ink in a reservoir that supplies the ink to the nozzles.

20. The droplet discharge method of claim 18, wherein the discharge amounts of the droplets respectively discharged on the substrate through the nozzles according to the ink drop map are identical to each other.
